(19) United States
(12) Patent Application Publication
(10) Pub. No.: US 2026/0004987 A1
(43) Pub. Date: Jan. 1, 2026

(54) ION SOURCE WITH MULTIPLE INTEGRATED ARC CHAMBERS

(71) Applicant: Axcelis Technologies, Inc., Beverly, MA (US)

(72) Inventors: Wilhelm Peter Platow, Newburyport, MA (US); Neil J. Bassom, Hamilton, MA (US)

(21) Appl. No.: 19/250,639

(22) Filed: Jun. 26, 2025

Related U.S. Application Data
(60) Provisional application No. 63/665,516, filed on Jun. 28, 2024.

(51) Int. Cl. H01J 27/14; H01J 37/08; H01J 37/317

(52) U.S. Cl. CPC H01J 27/14; H01J 37/08; H01J 37/3171

(57) ABSTRACT

An ion source has an arc chamber and multiple electrode pairs that define a respective plasma column axis within the arc chamber. A source magnet surrounds the arc chamber and defines pole pairs, each respectively associated with the electrode pairs to confine a plasma to the respective plasma column axis. The source magnet can be an electromagnet or a permanent magnet. The electromagnet has coils and a magnetic core to define the pole pairs and confine the plasma to the respective plasma column based on a coil current supplied to the coils. The magnetic core can have movable core members to magnetically couple each of the plurality of pole pairs. The permanent magnet has a magnetic core and movable core members to selectively magnetically couple the permanent magnet to each of the plurality of pole pairs.

### REFERENCE TO RELATED APPLICATIONS

This application claims the benefit of U.S. Provisional Application Ser. No. 63/665,516 filed Jun. 28, 2024, entitled, “ION SOURCE WITH MULTIPLE INTEGRATED ARC CHAMBERS”, the contents of all of which are herein incorporated by reference in their entirety.

### FIELD

The present invention relates generally to ion implantation systems and methods, and more specifically to an ion source having arc chamber with a selectable plasma column configuration.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type doped material, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energizes and directs the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining or improving desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

Ion sources (commonly referred to as arc discharge ion sources) generate ion beams used in implanters and can include heated filament cathodes for creating ions that are shaped into an appropriate ion beam for wafer treatment. U.S. Pat. No. 5,497,006 to Sferlazzo et al., for example, discloses an ion source having a cathode supported by a base and positioned with respect to a gas confinement chamber for ejecting ionizing electrons into the gas confinement chamber. The cathode of the Sferlazzo et al. is a tubular conductive body having an endcap that partially extends into the gas confinement chamber. A filament is supported within the tubular body and emits electrons that heat the endcap through electron bombardment, thereby thermionically emitting ionizing electrons into the gas confinement chamber.

Conventionally, the filament is located at one side of the chamber. In many popular ion sources, an indirectly heated cathode (IHC) is implemented, wherein a tungsten cap is positioned over the filament, and whereby the filament heats the cap, while the cap protects the filament in order to increase a lifetime of the ion source. The cap or cathode, however, is sputtered away over time. As such, the thickness of cap is made large, whereby the filament is heated to high temperatures to emit a substantial amount of electrons. The cap in this instance thus acts like a filament to emit electrons, but because of its significant thickness, a longer life has been attainable.

The lifetime of ion sources is a significant concern for ion implanters, where failure of the ion source can lead to unwanted scheduled maintenance and downtime. Failure of the cathode, for example, is typically the dominant factor for ion source life, particularly when forming multi-charged arsenic ion beams.

### SUMMARY

A lifetime of an ion source can be a significant concern for an ion implantation system, as maintenance of the ion source can lead to substantial downtime. The present disclosure provides an ion source having an arc chamber configured to selectively form a plurality of intersecting plasma columns defined by respective plurality of electrode pairs, whereby the ion source can substantially increase the lifetime of the ion source. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one example of the present disclosure, an ion source is provided, wherein the ion source comprises an arc chamber and a plurality of electrode pairs. Each of the plurality of electrode pairs define a respective plasma column axis within the arc chamber, wherein each of the plurality of electrode pairs are configured to selectively form a respective plasma therebetween based, at least in part, on an electrical potential supplied therebetween. A source magnet generally surrounds the arc chamber.

In one example, the source magnet comprises one or more coils and a magnetic core, wherein the magnetic core defines a plurality of pole pairs. Each of the plurality of pole pairs, for example, is respectively associated with each of the plurality of electrode pairs, wherein each of the plurality of pole pairs is configured to selectively confine the respective plasma to a respective plasma column along the respective plasma column axis based, at least in part, on a coil current selectively supplied to the one or more coils. In one example, an aperture is defined in a wall of the arc chamber, wherein the aperture is configured to emit or extract ions associated with the respective plasma column from the arc chamber.

Each of the plurality of electrode pairs, for example, respectively comprise a cathode and a repeller positioned along the respective plasma column axis. The cathode can comprise an indirectly heated cathode. For example, the plurality of electrode pairs comprise a first cathode and a first repeller positioned along a first plasma column axis, as well as a second cathode and a second repeller positioned along a second plasma column axis, wherein the first plasma 20) column axis and the second plasma column axis are non-parallel. In another example, the plurality of electrode pairs can further comprise a third cathode and a third repeller positioned along a third plasma column axis, wherein the first plasma column axis, the second plasma column axis, and the third plasma column axis are non-parallel.

In accordance with another example, the magnetic core can further comprise one or more movable core members, wherein the one or more movable core members are configured to selectively magnetically couple the return member to each of the plurality of pole pairs. The one or more movable core members can be configured to rotate or translate, thereby selectively magnetically coupling the return member to each of the plurality of pole pairs.

A controller, for example, can be configured to selectively supply coil current from a coil current supply to the one or more coils based on a desired one of the respective plasma column axis associated with each of the plurality of electrode pairs.

In accordance with another aspect of the disclosure, an ion source is provided, comprising an arc chamber and a plurality of electrode pairs, wherein each of the plurality of electrode pairs define a respective plasma column axis within the arc chamber. A source magnet apparatus generally surrounds the arc chamber, wherein the source magnet apparatus defines a plurality of pole pairs, and wherein each of the plurality of pole pairs is respectively associated with each of the plurality of electrode pairs and configured to respectively confine a plasma to the respective plasma column axis.

In one example, the source magnet apparatus comprises a source electromagnet. The source electromagnet can generally surround the arc chamber and comprises one or more coils and a magnetic core. The magnetic core, for example, further defines the plurality of pole pairs, and wherein each of the plurality of pole pairs is configured to selectively confine the respective plasma to the respective plasma column along the respective plasma column axis based, at least in part, on a coil current selectively supplied to the one or more coils. A coil current supply can be configured to selectively supply the coil current selectively to the one or more coils, and a controller can be configured to selectively supply the coil current from the coil current supply to the one or more coils based on a desired one of the respective plasma column axis associated with each of the plurality of electrode pairs.

The magnetic core, for example, can comprise a return member, wherein the return member is shared by the plurality of pole pairs. The magnetic core can further comprise one or more movable core members, wherein the one or more core movable members are configured to selectively magnetically couple the return member to each of the plurality of pole pairs. The one or more movable core members can be configured to rotate or translate, thereby selectively magnetically coupling the return member to each of the plurality of pole pairs.

In another example, the source magnet apparatus comprises a permanent magnet and a magnetic core, wherein the magnetic core further comprises one or more movable core members, and wherein the one or more movable core members are configured to selectively magnetically couple the permanent magnet to each of the plurality of pole pairs. The one or more movable core members can be selectively positioned with respect to the magnetic core and can be configured to selectively confine the respective plasma to the respective plasma column along the respective plasma column axis based, at least in part, on the selectable position of the one or more movable core members.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic diagram of an exemplary vacuum system utilizing an ion source in accordance with several aspects of the present disclosure.

FIG. 2 is a schematic diagram of a side view of an example arc chamber in accordance with several aspects of the present disclosure.

FIG. 3 is a schematic diagram of another example arc chamber in accordance with several aspects of the present disclosure.

FIG. 4 is a schematic diagram of yet another example arc chamber in accordance with several aspects of the present disclosure.

FIGS. 5A-5B are schematic diagrams of an example ion source in various configurations in accordance with several aspects of the present disclosure.

FIGS. 6A-6B are schematic diagrams of an example magnetic coupling in an ion source in various configurations in accordance with several aspects of the present disclosure.

FIGS. 7A-7B are schematic diagrams illustrating an example of a source electromagnet configured for providing respective orientations of first and second magnetic fields.

FIGS. 8A-8C are schematic diagrams illustrating an example of a source magnet comprising a permanent magnet configured for providing respective orientations of first and second magnetic fields.

FIGS. 9A-9C are schematic diagrams illustrating an example of a source magnet comprising a plurality of permanent magnets configured for providing respective orientations of first and second magnetic fields.

FIG. 10 is a flow diagram illustrating a method for improving a lifetime of an ion source in accordance with various aspects of the present disclosure.

### DETAILED DESCRIPTION

The present disclosure is directed generally toward an ion implantation system and an ion source associated therewith. More particularly, the present disclosure is directed generally toward a novel ion source, whereby a lifetime of the ion source of the ion implantation is substantially increased over conventional ion source. Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

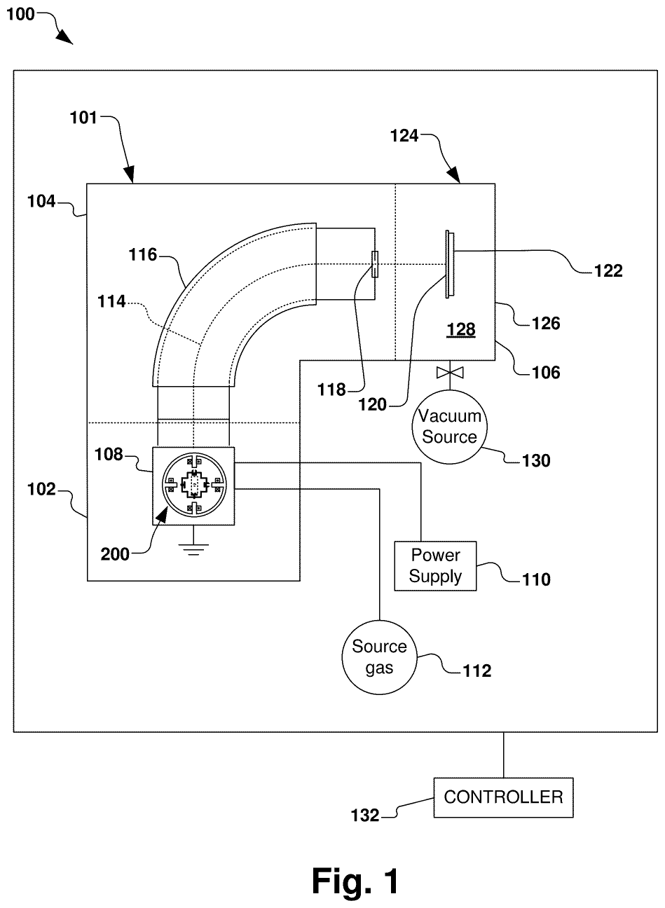

Referring now to the Figures, in order to gain a better appreciation of various aspects of the disclosure, FIG. 1 illustrates an exemplified vacuum system 100 that may implement various apparatus, systems, and methods of the present disclosure. The vacuum system 100 in the present example comprises an ion implantation system 101, however various other types of vacuum systems are also contemplated, such as plasma processing systems, or other semiconductor processing systems. The ion implantation system 101, for example, comprises a terminal 102, a beamline assembly 104, and an end station 106.

Generally speaking, an ion source 108 in the terminal 102 is coupled to a power supply 110, whereby a source gas 112 (also called a dopant gas) supplied thereto is ionized into a plurality of ions to form an ion beam 114. The ion beam 114 in the present example is directed through a beam-steering apparatus 116, and out an aperture 118 towards the end station 106. In the end station 106, the ion beam 114 bombards a workpiece 120 (e.g., a semiconductor such as a silicon wafer, a display panel, etc.), which is selectively clamped or mounted to a chuck 122 (e.g., an electrostatic chuck or ESC). Once embedded into the lattice of the workpiece 120, the implanted ions change the physical and/or chemical properties of the workpiece. Because of this, ion implantation is used in semiconductor device fabrication and in metal finishing, as well as various applications in materials science research.

The ion beam 114 of the present disclosure can take any form, such as a pencil or spot beam, a ribbon beam, a scanned beam, or any other form in which ions are directed toward end station 106, and all such forms are contemplated as falling within the scope of the disclosure.

According to one exemplary aspect, the end station 106 comprises a process chamber 124, such as a vacuum chamber 126, wherein a process environment 128 is associated with the process chamber. The process environment 128 within the process chamber 124, for example, comprises a vacuum produced by a vacuum source 130 (e.g., a vacuum pump) coupled to the process chamber and configured to substantially evacuate the process chamber. Further, a controller 132 is provided for overall control of the vacuum system 100.

The present disclosure provides an apparatus configured to increase beam current and utilization of the ion source 108 while decreasing downtime of the ion source in the ion implantation system 101 discussed above. It shall be understood that the apparatus of the present disclosure may be implemented in various semiconductor processing equipment such as CVD, PVD, MOCVD, etching equipment, and various other semiconductor processing equipment, and all such implementations are contemplated as falling within the scope of the present disclosure. The apparatus of the present disclosure further advantageously increases the length of usage of the ion source 108 between preventive maintenance cycles, and thus increases overall productivity and lifetime of the vacuum system 100.

The ion source 108, for example, plays a large role in the ion implantation system 101. As such, the performance of the ion source 108 can play a large role in metrics associated with the ion implantation system 101, such as throughput, uptime, glitch rate, as well as desired implantation parameters such as energy states of the desired ion species.

For example, when implanting high energy arsenic (As) ions into the workpiece 120, multiply-charged arsenic ions are typically extracted from the ion source 108 to form the ion beam 114. Arsenic, however, typically yields a high sputter rate within the ion source 108 due to its high atomic mass. A high arc voltage and arc current can also be provided by the power supply 110 for multi-charge operation, thus further increasing the sputter rate seen on components such as cathodes (not shown in FIG. 1) within the ion source 108. In conventional systems, such sputtering can lead to a decreased lifetime of the cathode of the ion source. To a degree, increasing a thickness of the cathode can increase its lifetime; however, the degree to which the thickness of the cathode can be increased in order to prolong its lifetime is limited due to difficulties associated with a control of heating and operation of such thickened cathodes.

The present disclosure advantageously increases the lifetime of the ion source 108, whereby a novel configuration of a plurality of electrode pairs within an arc chamber of the ion source are provided, as well as a novel architecture and control of a source magnet positioned around the arc chamber. The ion source can be configured to have power selectively applied to various combinations of the plurality of electrode pairs and to variously configure the source magnet to select one of a plurality of plasma column axes defined by the plurality of electrode pairs and poles of the source magnet.

The present disclosure appreciates that a lifetime of an ion source can be deleteriously affected by type and condition of ions extracted therefrom. For example, an extraction of multiply-charged arsenic ion beams from the ion source can yield a short lifetime of the ion source, as arsenic has a high sputter rate due to its high atomic mass. Additionally, a high arc voltage and current is associated with multi-charge operation of the ion source can further increase the sputter rate. Increasing material thicknesses of components such as a cathode associated with the ion source can prolong the lifetime of the ion source, but the increase in such material thicknesses can be limited to difficulties associated with quickly heating and controlling an electron emission from such a cathode.

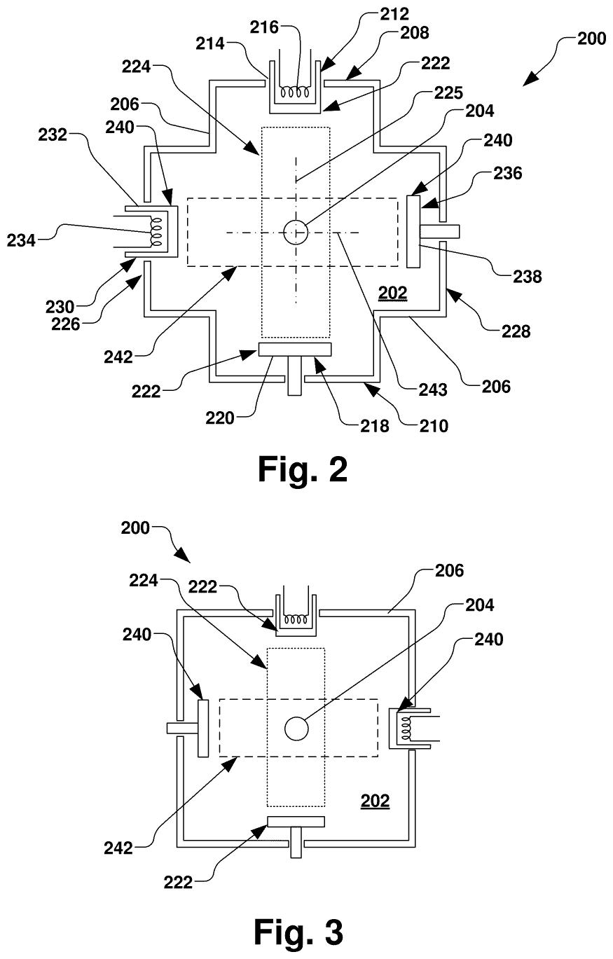

In accordance with the present disclosure, FIG. 2, for example, illustrates an example of an arc chamber 200, wherein the arc chamber defines an enclosed region 202 for forming ions. The ion beam 114 of FIG. 1, for example, can be extracted through an extraction aperture 204 (out of page plane) defined in the arc chamber 200 of the ion source 108. The arc chamber 200 of FIG. 2, for example, comprises sidewalls 206 (e.g., angled sidewalls) configured to minimize a volume of the enclosed region 202.

The arc chamber 200 of FIG. 2, for example, has a first end 208 and a second end 210, wherein a first electrode 212 is positioned proximate to the first end of the arc chamber. The first electrode 212, in the present example, is configured as a first indirectly heated cathode (first IHC) 214, whereby a first filament 216 is disposed within the first indirectly heated cathode to heat and emit electrons from the first IHC through thermionic emission. A second electrode 218 for example, is further positioned generally opposite the first electrode 212 and proximate to the second end 210 of the arc chamber 200. In the present example, the second electrode 218 comprises a first repeller 220 (also called an anticathode).

The first electrode 212 and the second electrode 218, for example, generally define a first electrode pair 222, whereby the first electrode pair is configured to form a first plasma column 224 (illustrated by dotted lines) therebetween along a first plasma column axis 225, whereby the formation of the first plasma column is based, at least in part, on an electrical potential (also called an arc voltage) applied to the first electrode and second electrode. The arc voltage, for example, can be applied to the first IHC 214, whereby the first plasma column 224 charges the first repeller 220 to the electrical potential of the first IHC. In some examples, while not shown, an electrical connector (e.g., a wire or conductive strap) can electrically couple the first IHC 214 to the first repeller 220 to ensure that the first IHC and the first repeller are at the same electrical potential. As such, negative arc voltage can be defined from the first IHC 214 and the first repeller 220 to the sidewalls 206 of the arc chamber 200, whereby electrons from the first IHC (at a negative potential) are attracted to the sidewalls. However, such electrons are trapped by spiraling around magnetic field lines between the first IHC 214 and the first repeller 220, as will be appreciated infra.

The arc chamber 200 of FIG. 2, for example, further has a third end 226 and a fourth end 228, wherein a third electrode 230 is positioned proximate to the third end of the arc chamber. The third electrode 230, in the present example, is also configured as a second indirectly heated cathode (second IHC) 232, whereby a second filament 234 is disposed within the second indirectly heated cathode to heat and emit electrons from the second IHC through thermionic emission. A fourth electrode 236 for example, is further positioned proximate to the fourth end 228 of the arc chamber 200. In the present example, the fourth electrode 236 comprises a second repeller 238. The third electrode 230 and the fourth electrode 236, for example, generally define a second electrode pair 240, whereby the second electrode pair is configured to form a second plasma column 242 (illustrated by dashed lines) therebetween along a second plasma column axis 243, whereby the formation of the second plasma column is based, at least in part, on an electrical potential applied to the third electrode and fourth electrode.

Again, in some examples, while not shown, another electrical connector (e.g., a wire or conductive strap) can electrically couple the second IHC 232 to the second repeller 238 to ensure that the second IHC and second first repeller are at the same electrical potential. Further, negative arc voltage can be defined from the second IHC 232 and the second repeller 238 to the sidewalls 206 of the arc chamber 200, whereby electrons from the second IHC (at a negative potential) are attracted to the sidewalls. Again, such electrons are trapped by spiraling around magnetic field lines between the second IHC 232 and the second repeller 238.

In accordance with one example, only one of the first electrode pair 222 or the second electrode pair 240 are energized by the electrical potential at any given time. As such, when one of the first electrode pair 222 or the second electrode pair 240 is energized, the other of the first electrode pair or the second electrode pair that is not energized by the electrical potential can be selectively electrically coupled (e.g., electrically shorted) to the sidewalls 206 of the arc chamber 200 in order to avoid charging thereof. It is to be noted that, while not shown, the second electrode 218 and fourth electrode 236 can alternatively comprise respective indirectly heated cathodes, as provided in co-owned U.S. Pat. No. 11,798,775, the contents of which is incorporated by reference in its entirety. Further, any of the first electrode 212, second electrode 218, third electrode 230, and fourth electrode 236 can comprise any of a variety of electrodes known to one of skill in the art, and all such electrodes are contemplated as falling within the scope of the present disclosure.

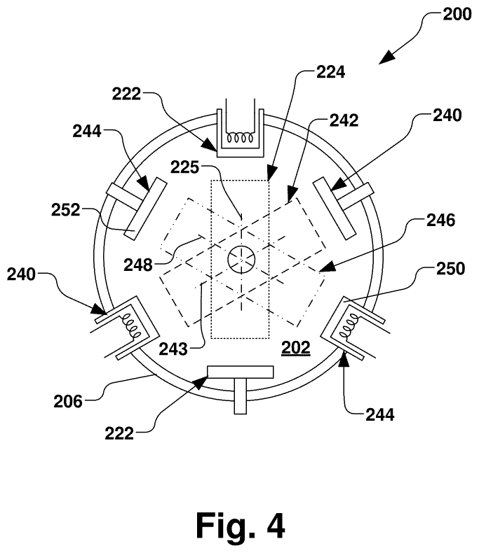

Further, the present disclosure contemplates various configurations of the sidewalls 206 of the arc chamber 200. For example, while the sidewalls 206 shown in FIG. 2 are configured to minimize the volume of the enclosed region 202 (e.g., a cross-shaped volume), FIG. 3 illustrates the sidewalls 206 being extended (e.g., a rectangular or square-shaped volume). The present disclosure further contemplates sidewalls 206 as being linear and substantially orthogonal to one 20) another, as illustrated in FIGS. 2 and 3, as well as being rounded, such as illustrated in FIG. 4.

FIG. 4 further illustrates a third electrode pair 244 configured to define a third plasma column 246 (illustrated in broken lines) along a third plasma column axis 248 in a manner similar to that discussed above with regards to the first electrode pair 222 and second electrode pair 240, whereby the third electrode pair can have similar features. For example, the third plasma column 246 is defined along the third plasma column axis 248 between a fifth electrode 250 and a sixth electrode 252 of the third electrode pair. In the present example, the first electrode pair 222, second electrode pair 240, and third electrode pair 244 have similar configurations, whereby the first plasma column axis 225, second plasma column axis 243, and third plasma column axis 248 are offset from one another by a multiple of approximately sixty degrees. As such, the present example contemplates extending a lifetime of the ion source 108 of FIG. 1 by three or more times that of a conventional ion source. While not explicitly shown, any number of electrode pairs and various configurations and offsets therebetween are contemplated as falling within the scope of the present disclosure.

Referring again to the example shown in FIG. 2, the first plasma column axis 225 is generally perpendicular to the second plasma column axis 243 (e.g., orthogonal), whereby only one of the first electrode pair 222 or second electrode pair 240 is activated at a time, while the other of the first electrode pair or second electrode pair is grounded to the sidewall 206 of the arc chamber 200. As such, the present disclosure advantageously provides an extended lifetime of the arc chamber 200 (e.g., the ion source 108 of FIG. 1), as once one of the first electrode pair 222 or the second electrode pair 240 is determined to have reached the end of its lifetime (e.g., by so-called punch through or electrical shorting to the sidewall 206), the other of the first or second electrode pairs May be activated. Accordingly, an operator or the controller 132 of FIG. 1 can advantageously switch power via relays or other mechanisms associated with the first and second electrode pairs, thus extending a lifetime of the ion source by approximately double, as compared to conventional ion sources.

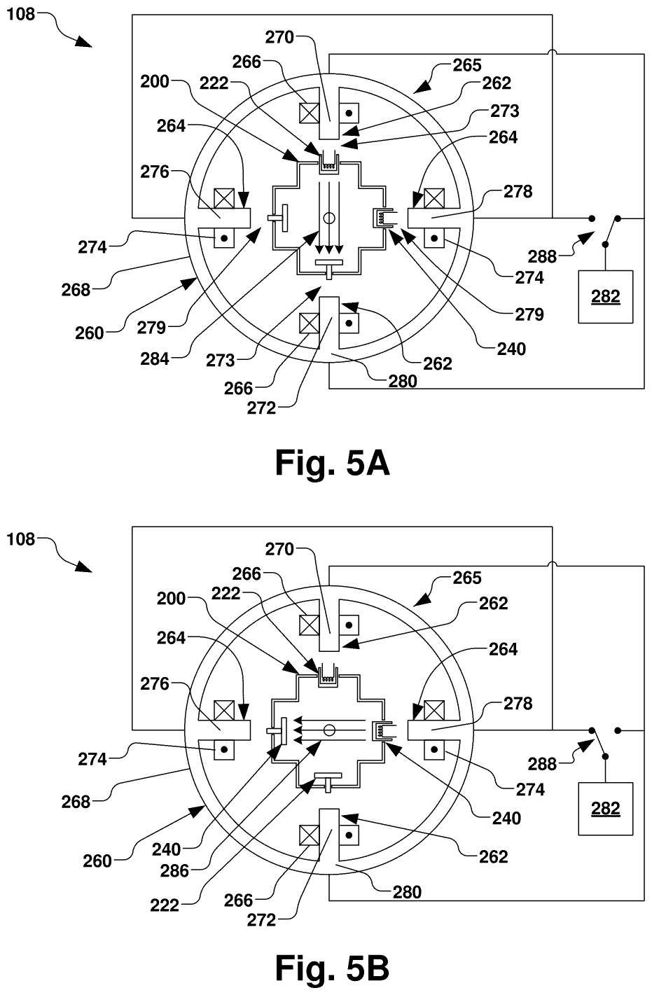

In accordance with another example aspect of the present disclosure, FIGS. 5A-5B illustrate a source magnet 260 generally surrounding or bracketing the arc chamber 200. The arc chamber 200 and the source magnet 260, for example, can generally define the ion source 108 of FIG. 1. The source magnet 260 of FIGS. 5A-5B, for example, comprises a first magnet 262 and a second magnet 264. In the present example, the source magnet 260 comprises an electromagnet 265. The first magnet 262 in the present example is defined by a first coil 266 that is wound around a magnetic core 268, thus defining a first pole 270 and a second pole 272 of the first magnet that are separated by a first gap 273.

The second magnet 264 in the present example is defined by a second coil 274 that is would around the magnetic core 268, thus defining a third pole 276 and a fourth pole 278 of the second magnet that are separated by a second gap 279. A return yoke 280 (also called a yoke or return leg), for example, magnetically couples the first pole 270 and the second pole 272 of the first magnet 262, as well as the third pole 276 and the fourth pole 278 of the second magnet 264, thereby guiding the magnetic field or magnetic flux. The magnetic core 268, for example, is comprised of magnetic steel and can take various forms and shapes, as will be discussed further infra.

The first magnet 262 and the second magnet 264 in the present example are further respectively associated with the first electrode pair 222 and second electrode pair 240 of the ion source 108. A magnet power supply 282, for example, is selectively electrically coupled to one of the first coil 266 or the second coil 274, whereby the magnet power supply is configured to pass a coil current through a respective one of the first coil or second coil, thereby defining a respective first magnetic field 284 (illustrated by arrows) between the first pole 270 and the second pole 272 of the first magnet 262 illustrated in FIG. 5A, or defining a second magnetic field 286 (illustrated by arrows) between the third pole 276 and the fourth pole 278 of the second magnet 264 illustrated in FIG. 5B.

Switching of the coil current from the magnet power supply 282, and thus activation of the respective first magnet 262 and the second magnet 264 of FIGS. 5A-5B, for example, can be achieved via a switch 288 (e.g., an electrical switch, relay, control electronics, etc.). Alternatively, while not shown, the magnet power supply 282 can comprise separate power supplies respectively electrically coupled to each of the first coil 266 and the second coil 274, whereby the switching of the coil current to one of the first coil 266 or the second coil 274 can be accomplished by selectively powering the respective separate power supply.

Accordingly, the source magnet 260 of FIGS. 5A-5B is thus configured to selectively confine the respective plasma to a respective plasma column along the respective plasma column axis based, at least in part, on a current selectively applied to the one or more coils. For example, the coil current supplied between the first pole 270 and the second pole 272 of the first magnet 262 illustrated in FIG. 5A can confine the first plasma column 224 of FIG. 2 to between the first electrode pair 222. Similarly, supplying the coil current between the third pole 276 and the fourth pole 278 of the second magnet 264 illustrated in FIG. 5B can confine the second plasma column 242 of FIG. 2 to between the second electrode pair 240. Accordingly, switching between operation of the first electrode pair 222 and the second electrode pair 240 can be accomplished by simultaneous or concurrent switching between operation and respective magnetic field orientation of the first magnet 262 and the second magnet 264.

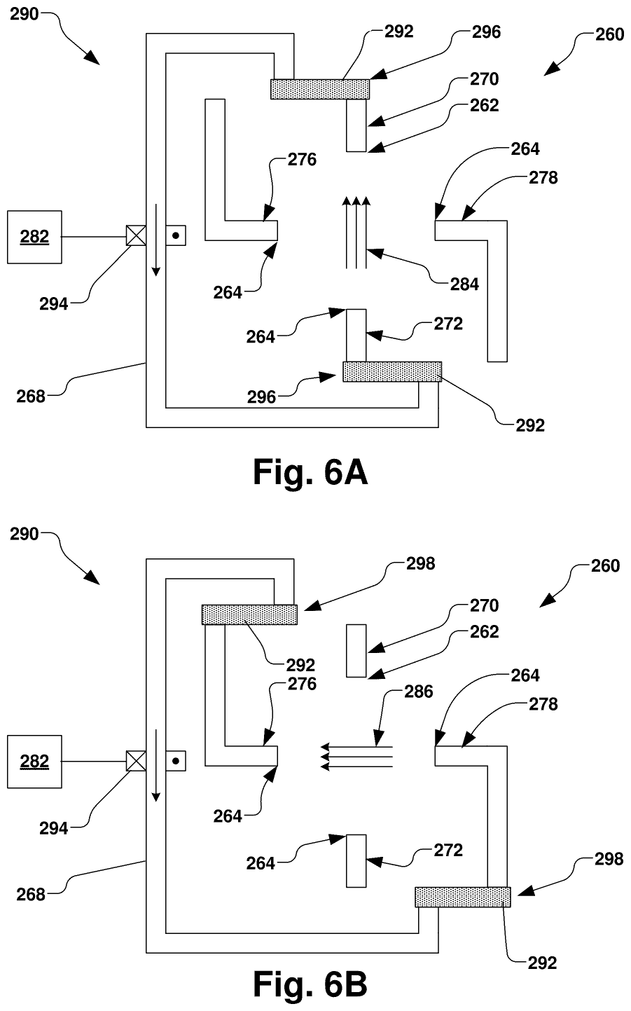

In accordance with another example, FIGS. 6A-6B illustrate the source magnet 260 as comprising a source electromagnet 290 configured to provide 20) selectable magnetic coupling to define the first magnet 262 and the second magnet 264, whereby one or more movable core members 292 (e.g., one or more magnetic steel members) are configured to mechanically translate or rotate to provide selective magnetic coupling of the magnetic core 268. It is noted that the arc chamber 200 of FIG. 2 is not illustrated in FIGS. 6A-6B for simplicity. However, in a manner similar to that shown in FIGS. 5A-5B, it is to be appreciated that the arc chamber 200, for example, may be provided within the source electromagnet 290 of FIGS. 6A-6B to define the respective first magnetic field 284 and the second magnetic field 286.

The magnet power supply 282 of FIGS. 6A-6B, for example, can be electrically coupled to a common coil 294, whereby the magnet power supply is configured to pass the coil current through common coil. Accordingly, when the one or more movable core members 292 are positioned in a first position 296 illustrated in FIG. 6A, the first magnetic field 284 can be established between the first pole 270 and the second pole 272 of the first magnet 262 by the coil current passing through the common coil 294. When the one or more movable core members 292 are positioned in a second position 298 illustrated in FIG. 6B, the second magnetic field 286 can be established between the third pole 276 and the fourth pole 278 of the second magnet 264 by the coil current passing through the common coil 294.

Thus, various portions of the magnetic core 268 are selectively magnetically coupled together by the one or more movable core members 292, whereby the magnetic field (e.g., the respective first magnetic field 284 and the second magnetic field 286) is trapped in the magnetic steel due to a minimal magnetic reluctance through the magnetic core (e.g., as compared to air). As such, magnetic flux (e.g., the first magnetic field 284 of FIG. 6A and the second magnetic field 286 of FIG. 6B) follows a path of least reluctance based on the selective magnetic coupling provided herein.

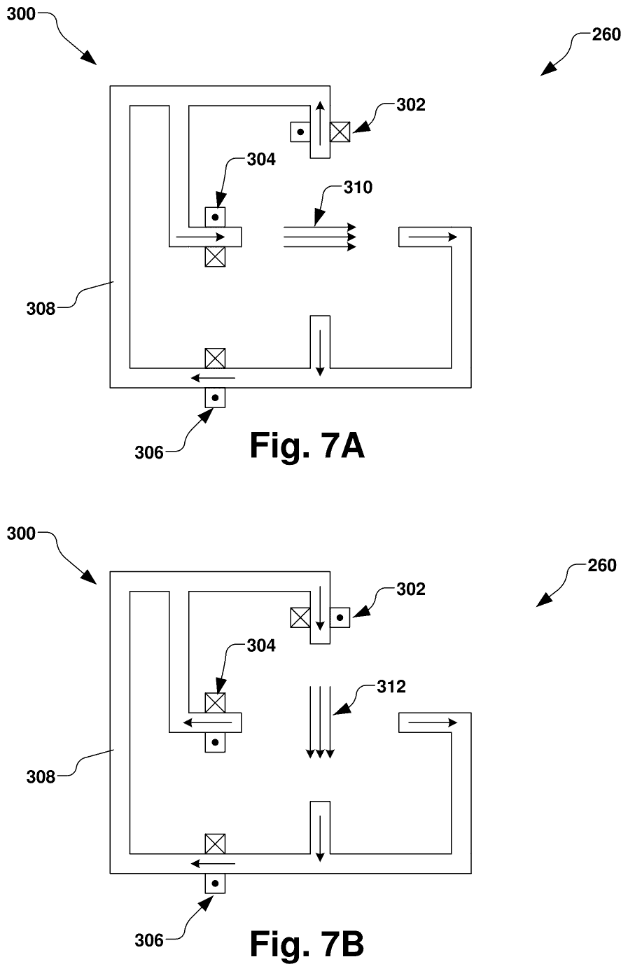

FIGS. 7A-7B illustrate another example of a source magnet 260 comprising a magnetic core 300 for surrounding an arc chamber (not shown) whereby a plurality of coils 302, 304, and 306 are arranged with respect to a magnetic core 308. The plurality of coils 302, 304, and 306 are configured to switch between dipole magnetic fields as indicated by pictogram (e.g., a cross showing current going into the page and a dot showing current coming out of page). The configuration of the magnetic core 308 shown in FIGS. 7A-7B, for example, provides a rotation of the primary magnetic field (e.g., orientation/direction) between a first magnetic field 310 shown in FIG. 7A and a second magnetic field 312 shown in FIG. 7B. The magnetic core 308, for example, comprises a return leg that can be in the same plane as the poles discussed above, or in another plane, whereby space considerations can be taken into account.

The present disclosure contemplates the controller 132 of FIG. 1, for example, being configured to supply a coil current from a coil current source (e.g., a power supply) to the one or more coils of the source electromagnet. The source electromagnet, for example, comprises a magnetic core (e.g., steel laminations or a yoke), whereby a configuration of the magnetic core and the coil current applied to the one or more coils defines a magnetic field in the ion source based on the intensity and polarity of the coil current.

The controller (e.g., a specialized or general controller or other switching apparatus), for example, can be operably coupled to the ion source, coil current source, and electrode power supply, whereby the controller is configured to selectively control the coil current supplied to the one or more coils. For example, the controller can be configured to control the polarity of the magnet current supplied from the coil current source to the one or more coils based on a selection of the desired plasma column axis. The controller, for example, can further selectively supply the coil current to only a predetermined number of the one or more coils based on the selection of the desired plasma column axis. For example, the controller can comprise a relay configured to selectively supply the coil current a first coil pair, while not supplying the coil current to a second coil pair, such as illustrated in FIGS. 5A-5B.

For example, the controller can be configured to couple only one of the first coil or the second coil to the coil current supply at a time, whereby the magnet is selectively controlled based on the desired operation of the first plasma column or the second plasma column.

The present disclosure contemplates various structures and methods for altering or switching a direction of an applied magnetic field to a plasma within the arc chamber 200 of FIG. 2, such as by selectively activating various portions of a source magnet 260, altering magnet circuitry, varying an arrangement of a coil or magnetic core, moving the arc chamber within a static magnetic field, or by rotating the source magnet 260 with respect to the arc chamber 200.

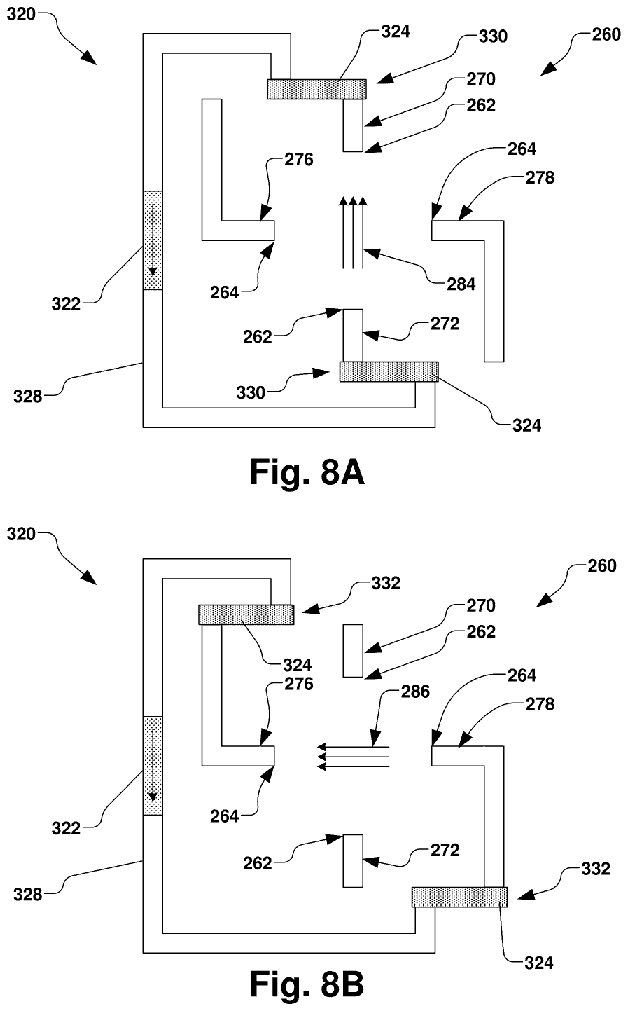

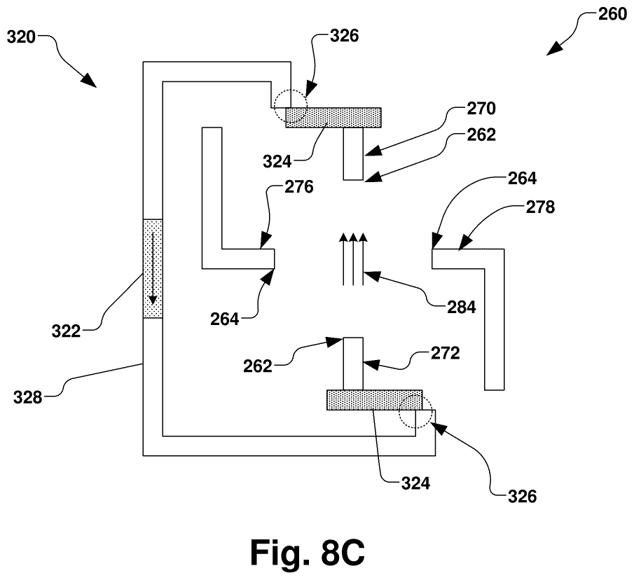

FIGS. 8A-8C illustrate another example of the present disclosure, whereby the source magnet 260 comprises a permanent source magnet 320. Conceptually, the permanent source magnet 320 of FIGS. 8A-8C, for example, comprises a permanent magnet 322 that replaces the common coil 294 shown in FIGS. 6A-6B. As discussed above in relation to the source electromagnet 290, the first magnetic field 284 of FIG. 6A and the second magnetic field 286 of FIG. 6B can be selectively controlled by control of the coil current to the common coil 294 associated with the source electromagnet.

Permanent magnets, however, can provide fixed magnetic fields, and are generally not controllable by the variations in electrical current that is afforded by the source electromagnet 290 of FIGS. 6A-6B. Therefore, in the example of the permanent source magnet 320 of FIGS. 8A-8C, a position of one or more movable core members 324 (e.g., magnetic steel members configured to mechanically translate or rotate with respect to the magnetic core 268), controls not only the orientation of the first magnetic field 284 of FIG. 8A and the second magnetic field 286 of FIG. 8B, but also controls the respective intensities or strengths of such magnetic fields. For example, as illustrated in FIG. 8C, the strength of the first magnetic field 284 can be controlled by an overlap 326 of the one or more movable core members 324 with respect to a magnetic core 328, whereby the magnetic resistance or reluctance can be made larger or smaller based on the amount of overlap.

Accordingly, when the one or more movable core members 324 are positioned in a first position 330 illustrated in FIG. 8A, the first magnetic field 284 can be established between the first pole 270 and the second pole 272 of the first magnet 262 by the magnetic coupling achieved between the first and second poles, the magnetic core 328, the permanent magnet 322 and the one or more movable core members. When the one or more movable core members 324 are positioned in a second position 332 illustrated in FIG. 8B, for example, the second magnetic field 286 can be established between the third pole 276 and the fourth pole 278 of the second magnet 264 by the magnetic coupling achieved between the third and fourth poles, the magnetic core 328, the permanent magnet 322 and the one or more movable core members. Furthermore, the one or more movable core members 324 can be configured to selectively vary the strength of the respective first magnetic field 284 and second magnetic field 286 of FIGS. 8A-8B by controlling the positions thereof, thus controlling the overlap 326 of FIG. 8C, as discussed above.

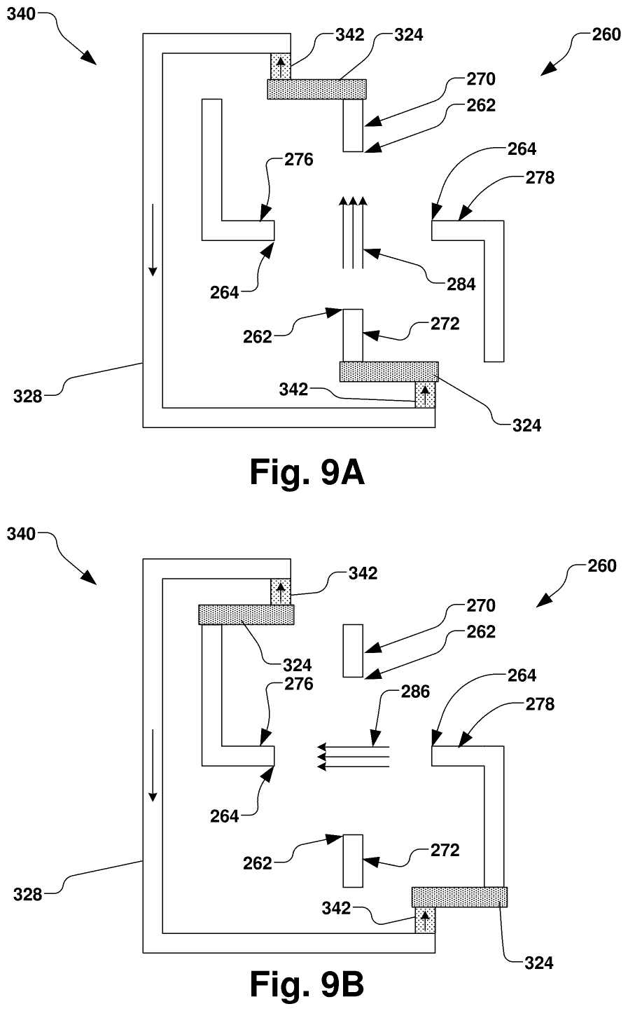

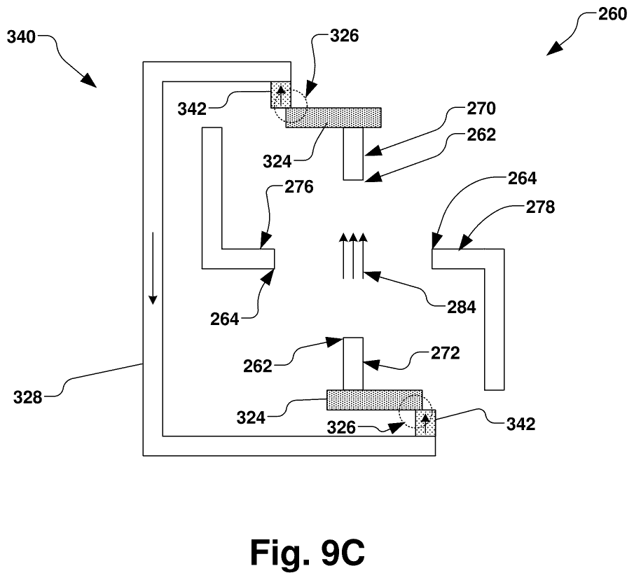

FIGS. 9A-9C illustrate yet another example of the present disclosure, whereby the source magnet 260 comprises a permanent source magnet 340 having a plurality of permanent magnets 342. Similar to that discussed above with reference to the permanent source magnet 320 shown in FIGS. 8A-8C, in the example of the permanent source magnet 340 of FIGS. 9A-9C, the position of the one or more movable core members 324 controls the orientation of the first magnetic field 284 of FIG. 9A and the second magnetic field 286 of FIG. 9B, as well as the intensities or strengths of the magnetic fields provided by the permanent source magnet, whereby the plurality of permanent magnets 342 are more proximate to the first pole 270, second pole 272, third pole 276 and the fourth pole 278. For example, as illustrated in FIG. 9C, the strength of the first magnetic field 284 can similarly be controlled by the overlap 326 of the one or more movable core members 324 with respect to the plurality of permanent magnets 342, whereby the magnetic resistance or reluctance can be made larger or smaller based on the amount of overlap.

The present disclosure further appreciates that numerous other shapes and configurations of the source magnets described herein are contemplated, including, but not limited to various configurations of the magnetic cores, the coils, the permanent magnets, and the movable core members. For example, varying arrangements of the poles, yoke, coil, etc., as well as the arc chamber and plurality of electrode pairs, can be tailored based on various configurations of an ion implantation system associated therewith. It shall be appreciated that all such configurations are contemplated as falling within the scope of the present disclosure.

In accordance with yet another exemplary aspect of the disclosure, the power supply and/or controller can comprise any power supply and/or controller that is operably coupled to the ion implantation system described herein that may be utilized for powering and controlling various components of the system.

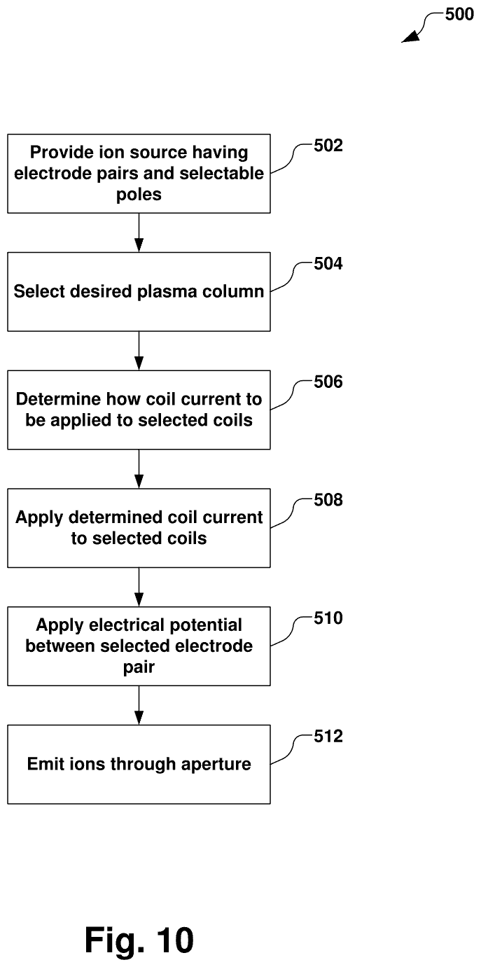

In accordance with another example aspect of the present invention, FIG. 10 illustrates a method 500 for operating an ion implantation system. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

The method 500, for example, provides an ion source in act 502, wherein the ion source comprises a plurality of electrode pairs disposed in an arc chamber generally surrounded by a source electromagnet, whereby the plurality of electrode pairs define a respective plurality of plasma column axes. The source electromagnet, for example, comprises a magnetic core and one or more coils, wherein the magnetic core defines a plurality of pole pairs associated with each of the plurality of plasma column axes, respectively.

A selection of a desired one of the plurality of plasma column axes is made in act 504, wherein can be based on one or more conditions associated with a desired implantation of ions into a workpiece. The one or more conditions, for example, can comprise one or more of a desired species or other property of the ions to be implanted into the workpiece. Alternatively, the one or more conditions can comprise a determined or predetermined lifetime associated with each of the plurality of pole pairs. For example, the selection of the desired one of the plurality of plasma column axes can be made in act 504 based on a determination that one or more of the plurality of cathodes is in a deficient state or has reached a predetermined lifetime.

In act 506, a determination of the coil current to be applied to the one or more coils is made in act 506, and can comprise determining a polarity of the coil current to be applied to the one or more coils based on the selection of the desired one of the plurality of plasma column axes in act 504. In another example, the one or more coils can comprise a plurality of coils, wherein each of the plurality of coils is respectively associated with one or more of the plurality of plasma column axes. As such, the determination of the coil current applied to the one or more coils in act 506 can further comprise a determination of one or more of the plurality of coils to which the coil current is to be applied, based on a configuration of the source electromagnet and the selection of the one of the plurality of plasma column axes in act 504.

In act 508, the coil current is applied to the respective one or more coils based on the selection of the desired one of the plurality of plasma column axes made in act 504. In act 510, an electrical potential is further applied to the electrode pair that is associated with the desired one of the plurality of plasma column axis selected in act 504, thereby forming a plasma of ions. Further, in act 510 any electrode pair that is not associated with the desired one of the plurality of plasma column axis can be electrically grounded in order avoid floating to an undesired potential. Accordingly, in act 512, the ions from the desired one of the plurality of plasma column axes is emitted through an aperture in the arc chamber, whereby an ion beam may be formed for implantation into a workpiece.

It is to be further appreciated that the above-described systems, apparatuses, and methodologies can be further practiced with the systems, apparatuses, and methods described in co-owned U.S. Pat. No. 11,823,858, the contents of which are incorporated by reference in their entireties.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

What is claimed is:

1. An ion source comprising:
an arc chamber;
a plurality of electrode pairs, wherein each of the plurality of electrode pairs define a respective plasma column axis within the arc chamber; and
a source magnet generally surrounding the arc chamber, wherein the source magnet defines a plurality of pole pairs, wherein each of the plurality of pole pairs is respectively associated with each of the plurality of electrode pairs and configured to respectively confine a respective plasma to the respective plasma column axis.

2. The ion source of claim 1, wherein each of the plurality of electrode pairs respectively comprises a cathode and a repeller.

3. The ion source of claim 2, wherein the cathode comprises an indirectly heated cathode.

4. The ion source of claim 1, wherein the plurality of electrode pairs comprise:
a first cathode and a first repeller positioned along a first plasma column axis; and
a second cathode and a second repeller positioned along a second plasma column axis, wherein the first plasma column axis and the second plasma column axis are non-parallel.

5. The ion source of claim 4, wherein the first plasma column axis is perpendicular to the second plasma column axis.

6. The ion source of claim 4, wherein the arc chamber comprises an aperture configured to release ions associated with the respective plasma therefrom, wherein the aperture is generally circular when viewed perpendicular to the first plasma column axis and the second plasma column axis.

7. The ion source of claim 4, wherein the plurality of electrode pairs further comprise a third cathode and a third repeller positioned along a third plasma column axis, wherein the first plasma column axis, the second plasma column axis, and the third plasma column axis are non-parallel.

8. The ion source of claim 7, wherein the first plasma column axis, the second plasma column axis, and the third plasma column axis are offset from one another by a multiple of approximately sixty degrees.

9. The ion source of claim 4, wherein the source magnet comprises a magnetic core defining the plurality of pole pairs, wherein the magnetic core further comprises a return member, wherein the return member is shared by the plurality of pole pairs.

10. The ion source of claim 1, wherein the source magnet comprises a source electromagnet, wherein the source electromagnet generally surrounds the arc chamber and comprises one or more coils and a magnetic core, wherein the magnetic core further defines the plurality of pole pairs, and wherein each of the plurality of pole pairs is configured to selectively confine the respective plasma to the respective plasma column along the respective plasma column axis based, at least in part, on a coil current selectively supplied to the one or more coils.

11. The ion source of claim 10, further comprising a coil current supply and a controller, wherein the controller is configured to selectively supply the coil current from the coil current supply to the one or more coils based on a desired one of the respective plasma column axis associated with each of the plurality of electrode pairs.

12. The ion source of claim 10, wherein the magnetic core comprises a return member, wherein the return member is shared by the plurality of pole pairs.

13. The ion source of claim 12, wherein the magnetic core further comprises one or more movable core members, wherein the one or more core movable members are configured to selectively rotate or translate, thereby selectively magnetically coupling the return member to each of the plurality of pole pairs.

14. The ion source of claim 10, wherein the one or more coils comprise a single coil associated with the plurality of pole pairs.

15. The ion source of claim 1, wherein the source magnet comprises a permanent magnet and a magnetic core, wherein the magnetic core further comprises one or more movable core members, wherein the one or more movable core members are configured to selectively magnetically couple the permanent magnet to each of the plurality of pole pairs.

16. The ion source of claim 15, wherein the one or more movable core members are selectively positioned with respect to the magnetic core and configured to selectively confine the respective plasma to the respective plasma column along the respective plasma column axis based, at least in part, on the selective positioning of the one or more movable core members.

17. The ion source of claim 15, wherein the magnetic core comprises a return member, wherein the return member is shared by the plurality of pole pairs.

18. The ion source of claim 17, wherein the one or more core movable members are configured to selectively rotate or translate, thereby selectively magnetically coupling the return member to each of the plurality of pole pairs.

19. An ion source comprising:
an arc chamber;
a plurality of electrode pairs, wherein each of the plurality of electrode pairs define a respective plasma column axis within the arc chamber, and wherein each of the plurality of electrode pairs are configured to selectively form a respective plasma therebetween based, at least in part, on an electrical potential supplied therebetween;
a source electromagnet generally surrounding the arc chamber and comprising one or more coils and a magnetic core, wherein the magnetic core defines a plurality of pole pairs, wherein each of the plurality of pole pairs is respectively associated with each of the plurality of electrode pairs, and wherein each of the plurality of pole pairs is configured to selectively confine the respective plasma to a respective plasma column along the respective plasma column axis based, at least in part, on a coil current selectively supplied to the one or more coils, and wherein the magnetic core further comprises one or more movable core members, wherein the one or more movable core members are configured to selectively rotate or translate, thereby selectively magnetically coupling the return member to each of the plurality of pole pairs; and
an aperture defined in a wall of the arc chamber, wherein the aperture is configured to emit or extract ions associated with the respective plasma column from the arc chamber.

20. The ion source of claim 19, further comprising:
a coil current supply configured to selectively supply the coil current to the one or more coils;
an electrode power supply configured to selectively supply the electrical potential between the plurality of electrode pairs; and
a controller, wherein the controller is configured to selectively supply the coil current to the one or more coils from the coil current supply based on a desired one of the respective plasma column axis associated with each of the plurality of electrode pairs, and wherein the controller is further configured to selectively supply the electrical potential between the plurality of electrode pairs from the electrode power supply based on the desired one of the respective plasma column axis associated with each of the plurality of electrode pairs.
